(19) United States
(12) Patent Application Publication
(10) Pub. No.: US 2012/0094046 A1
(43) Pub. Date: Apr. 19, 2012

(54) HOUSING FOR ELECTRONIC DEVICE AND METHOD FOR MAKING SAME

(75) Inventors: SHI-FENG WANG, Shenzhen (CN); KUAN-HUNG CHEN, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/051,035

(22) Filed: Mar. 18, 2011

(30) Foreign Application Priority Data
Oct. 14, 2010 (CN) 201010507128.9

(51) Int. Cl. B32B 1/02; C23F 1/32; C23F 1/00; C23F 1/16; C23C 14/34; H05K 13/00

(52) U.S. Cl. 428/35.9; 428/34.1; 204/192.12; 216/37

(57) ABSTRACT

A method for making a housing for an electronic device, including steps of: providing a substrate; forming a base paint layer on an outer surface of the substrate; forming a metallic layer with a metallic appearance on the base paint layer; forming a chemical resistant protective coating on the metallic layer, the protective coating having substantially the same shape as desired patterns; chemically removing the metallic layer not covered by the protective coat, the remainder of the metallic layer forming desirable patterns; and removing the protective coat. A housing made by the present method is provided.

### BACKGROUND

1. Technical field

The present disclosure generally relates to a housing for electronic devices and a method for making the housing.

2. Description of related art

Housings for electronic devices often have logos and patterns formed on conspicuous parts. Usually, the logos are formed by printing or painting the housing. However, printed or painted logos often have poor abrasion resistance, and may have a dull or lackluster appearance.

Therefore, there is room for improvement within the art.

### BRIEF DESCRIPTION OF THE DRAWINGS

Many aspects of the housing for electronic device and method for making the housing can be better understood with reference to the following drawings. The components in the drawings are not necessarily to scale, the emphasis instead being placed upon clearly illustrating the principles of the present housing and method for making the same.

FIG. 1 is a cross-section view of an exemplary embodiment of the present housing.

FIG. 2 is a block diagram of an exemplary process for making the present housing.

### DETAILED DESCRIPTION

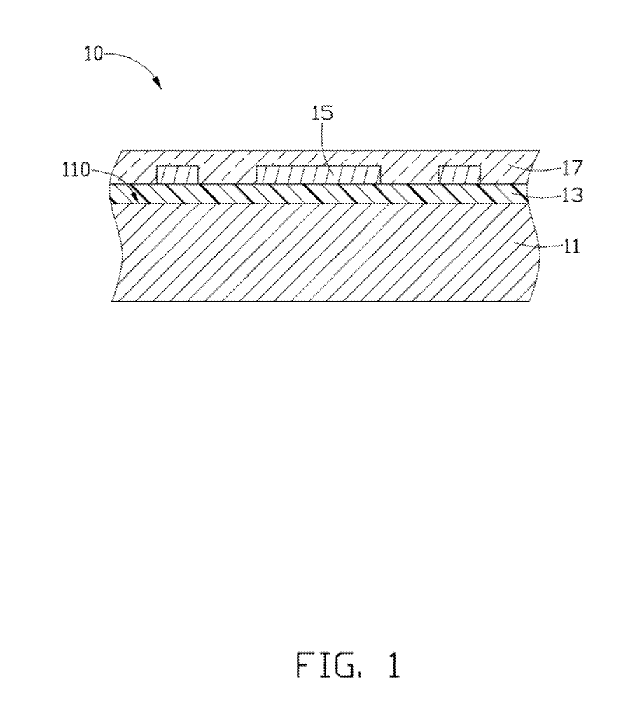

FIG. 1 shows an exemplary embodiment of a housing 10 for an electronic device such as a mobile phone. The housing 10 includes a substrate 11, a base paint layer 13, a metallic layer 15, and a transparent top paint layer 17.

The substrate 11 may be molded from plastic e.g., polymethyl methacrylate (PMMA), polythylene (PE), acrylonitrile-butadiene-styrene (ABS), or polycarbonate (PC). In another exemplary embodiment, the substrate 11 may be made of a metal. The substrate 11 has an outer surface 110.

The base paint layer 13 is directly formed on the outer surface 110. The base paint layer 13 may be made of an ultraviolet curable paint or a thermosetting paint. In this exemplary embodiment, the base paint layer is made using an ultraviolet curable paint. The base paint layer 13 can strengthen the bonding of the metallic layer 15 to the substrate 11. The thickness of the base paint layer 13 may be about 6-12 μm.

The metallic layer 15 is directly formed on the base paint layer 13 by vacuum coating using a material, metal or otherwise, having a metallic appearance. The metallic layer 15 forms patterns, such as logos, figures, or characters on the housing 10. When the housing 10 is used for a telecommunication electronic device, the metallic layer 15 need only appear to be metal and can be nonconductive to not interfere with the transmission of radio frequency signals (RF). In this exemplary embodiment, the metallic layer 15 is silvery white.

The top paint layer 17 is directly coated on the metallic layer 15 and portions of the base paint layer 13 not covered by the metallic layer 15. The top paint layer 17 may be made of an ultraviolet curable paint or a thermosetting paint. In this exemplary embodiment, the top paint layer 17 is made of ultraviolet curable paint. The top paint layer 17 may protect the metallic layer 15 from abrasion. The thickness of the top paint layer may be about 6-12 μm.

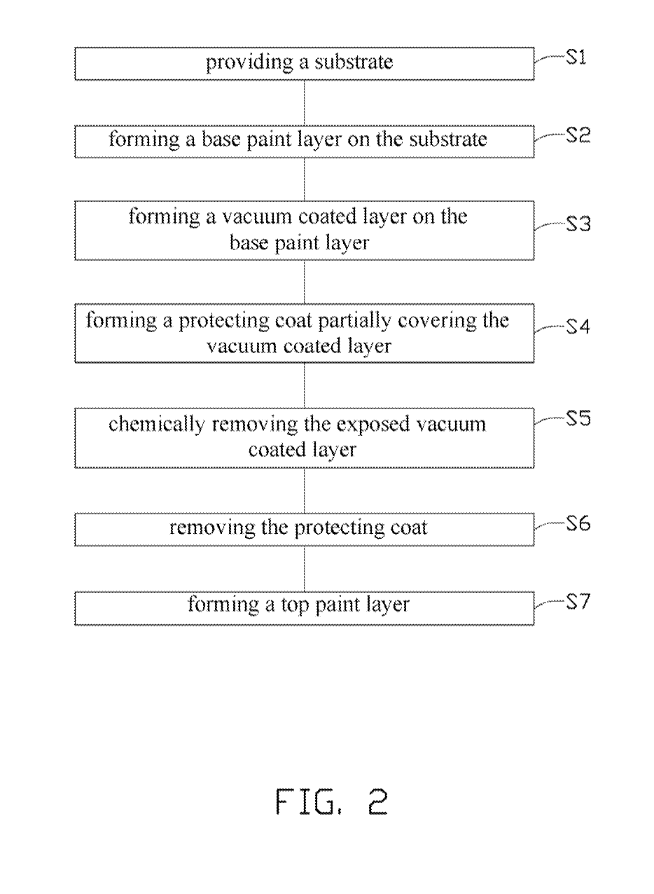

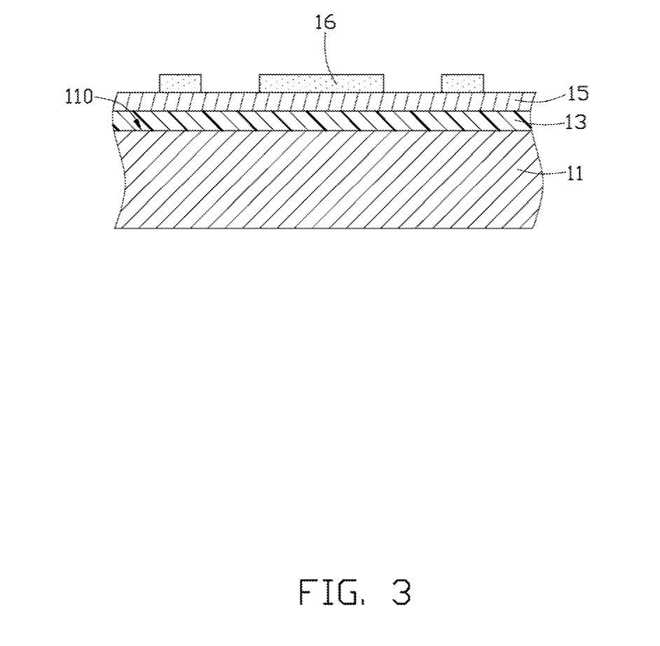

FIG. 2 shows an exemplary method for making the housing 10, which may include the following steps.

In step S1, the substrate 11 having the outer surface 110 is provided. The substrate 11 may be degreased.

In step S2, the base paint layer 13 may be spray painted on the outer surface 110 or applied by some other alternative methods, if available.

In step S3, the metallic layer 15 is formed on the base paint layer 13 by vacuum coating, such as evaporation or sputtering. The metallic layer 15 may have metallic appearance. In this step, the metallic layer 15 may cover the entire base paint layer 13 or portions of the base paint layer 13 predetermined to form patterns.

In step S4, referring to FIG. 3 a chemical resistant protective coating 16 is formed by, for example, printing on the metallic layer 15. The protective coating 16 has substantially the same shape as the desired patterns and partially covers the metallic layer 15. The protective coating 16 is comprised of materials resistant to chemical erosion such as chemical-resistant inks and paints, such as polyamide ink.

In step S5, portions of the metallic layer 15 not covered by the protective coating 16 can be chemically removed. The substrate 11 coated with the protective coating 16 may be immersed in an etching solution containing corrosive acid or basic, such as sodium hydroxide or hydrochloric acid. In this step, portions of the metallic layer 15 not covered by the protective coating 16 are chemically removed, and the remainder of the metallic layer 15 forms desirable patterns.

In step S6, the protective coating 16 can be removed from the metallic layer 15.

In step S7, the transparent top paint layer 17 can be formed on the remainder of the metallic layer 15 and the base paint layer 13 not covered with the metallic layer 15.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing for an electronic device, comprising:
a substrate, the substrate having an outer surface;
a base paint layer formed on the outer surface; and
a metallic layer with a metallic appearance forming a pattern on the base paint layer.

2. The housing as claimed in claim 1, wherein the substrate is made of plastic or metal.

3. The housing as claimed in claim 1, wherein the metallic layer is nonconductive.

4. The housing as claimed in claim 1, wherein the thickness of the base paint layer and the top paint layer are each about 6-12 μm.

5. The housing as claimed in claim 1, wherein the top paint layer and the base paint layer both are made of ultraviolet curable paint.

6. The housing as claimed in claim 1, wherein the patterns formed by the metallic layer are logos or characters.

7. The housing as claimed in claim 1, wherein the housing further includes a transparent top paint layer formed on the metallic layer and portions of the base paint layer not covered by the metallic layer.

8. A method for making a housing for an electronic device, comprising the steps of:
providing a substrate, the substrate having an outer surface;
forming a base paint layer on the outer surface;
vacuum coating a metallic layer having a metallic appearance on the base paint layer;
forming a chemical resistant protective coating on the metallic layer, the protective coating having substantially the same shape as desired patterns;
chemically removing the metallic layer exposed from the protective coat, the remainder of the metallic layer forming desirable patterns; and
removing the protective coat.

9. The method as claimed in claim 8, wherein the substrate is made of plastic or metal.

10. The method as claimed in claim 8, wherein the metallic layer is formed by evaporation or sputtering.

11. The method as claimed in claim 8 wherein the protective coating is comprised of chemical-resistant inks or paints.

12. The method as claimed in claim 11 wherein the protective coating is comprised of polyamide ink.

13. The method as claimed in claim 8 wherein in the chemically removing step, the substrate coated with the protective coating is immersed in an etching solution containing corrosive acid or basic.

14. The method as claimed in claim 13 wherein the etching solution contains sodium hydroxide or hydrochloric acid.

15. The method as claimed in claim 8 further comprising a step of forming a transparent top paint layer on the remainder of the metallic layer and the base paint layer not covered with the metallic layer after removing the protective coat.
